(19) United States
(12) Patent Application Publication
(10) Pub. No.: US 2012/0226966 A1
(43) Pub. Date: Sep. 6, 2012

(54) System and Method for Device Identification in a Communications System

(75) Inventor: Bin Chen, Schaumburg, IL (US)

(73) Assignee: FutureWei Technologies, Inc., Plano, TX (US)

(21) Appl. No.: 13/407,953

(22) Filed: Feb. 29, 2012

Related U.S. Application Data
(60) Provisional application No. 61/447,906, filed on Mar. 1, 2011.

(51) Int. Cl. H03M 13/09; G06F 11/10

(52) U.S. Cl. 714/807; 714/E11.032

(57) ABSTRACT

A method of transmitting an information sequence in a message includes embedding a first information sequence into an original payload of the message to produce an augmented payload and generating an original error check code using the augmented payload, the original error check code derived from the first information sequence. The method also includes transmitting the message, the message including the original payload and the original error check code.

This application claims the benefit of U.S. Provisional Application No. 61/447,906, filed on Mar. 1, 2011, entitled “System and Method for Device Identification in a Communications System,” which application is hereby incorporated herein by reference.

### TECHNICAL FIELD

The present disclosure relates generally to digital communications, and more particularly to a system and method for device identification in a communications system.

### BACKGROUND

WiMAX compliant communications systems are based on the series of IEEE 802.16 technical standards and are used to provide wireless broadband access service. Similarly, the Third Generation Partnership Project (3GPP) Long Term Evolution (LTE) and Long Term Evolution Advanced (LTE-Advanced) series of technical standards also provide for wireless broadband access service. Specifically, the IEEE 802.16m and 3GPP TLE-Advanced technical standards are all International Mobile Telecommunications—Advanced (IMT-Advanced) candidate standards and their basic physical technologies are similar, for example, both support Multiple Input, Multiple Output (MIMO) with Orthogonal Frequency Division Multiple Access (OFDMA) operation. However, some detailed technologies are different, especially in channel structure and signaling.

Machine to Machine (M2M) communications is a service based on a wireless communications system. Currently, both IEEE 802.16 and 3GPP LTE/LTE-Advanced define their own M2M requirements and features lists. In IEEE 802.16, M2M communications is referred to as IEEE 802.16p with system requirements including: low power consumption, support for large numbers of communications devices, small burst transmission, security support, and so forth. FIG. 1 illustrates an example of a M2M communications system in an IEEE 802.16 compliant communications system.

### SUMMARY OF THE DISCLOSURE

Example embodiments of the present disclosure which provide a system and method for device identification in a communications system.

In accordance with an example embodiment of the present disclosure, a method of transmitting an information sequence in a message is provided. The method includes embedding a first information sequence into an original payload of the message to produce an augmented payload, and generating an original error check code using the augmented payload, the original error check code derived from the first information sequence. The method also includes transmitting the message, the message including the original payload and the original error check code.

In accordance with another example embodiment of the present disclosure, a method of receiving a message by a receiving device is provided. The method includes receiving the message including an original payload and an original error check code, and embedding a first information sequence into the original payload to produce a local payload. The method also includes performing an error check on the local payload using the original error check code, and determining that the message is embedded with the first information sequence if the error check succeeded.

In accordance with another example embodiment of the present disclosure, a method of transmitting an information sequence in a message is provided. The method includes modifying an original payload of the message with a first information sequence to derive an augmented payload, and generating an original error check code using the original payload. The method also includes transmitting the message, the message including the augmented payload and the original error check code.

In accordance with another example embodiment of the present disclosure, a method of receiving a message by a receiving device is provided. The method includes receiving the message including an augmented payload and an original error check code, and modifying the augmented payload with a first information sequence to derive a local payload. The method also includes performing an error check on the local payload using the original error check code, and determining that the message is embedded with the first information sequence if the error check succeeded.

In accordance with another example embodiment of the present disclosure, a transmitting device is provided. The transmitting device includes a processor, and a transmitter operatively coupled to the processor. The processor embeds a first information sequence into an original payload of a message to produce an augmented payload, and generates an original error check code using the augmented payload, the original error check code derived from the first information sequence. The transmitter transmits the message, the message including the original payload and the original error check code.

In accordance with another example embodiment of the present disclosure, a transmitting device is provided. The transmitting device includes a processor, and a transmitter operatively coupled to the processor. The processor modifies an original payload of a message with a first information sequence to derive an augmented payload, and generates an original error check code using the original payload. The transmitter transmits the message, the message including the augmented payload and the original error check code.

One advantage of an embodiment is that techniques for identifying communications devices operating in a communications system that includes a large number of communications devices with little or no overhead are presented. The requirement of little or no overhead may help to minimize impact on communications system performance since the consumption of valuable bandwidth due to the overhead is reduced.

### BRIEF DESCRIPTION OF THE DRAWINGS

For a more complete understanding of the present disclosure, and the advantages thereof, reference is now made to the following descriptions taken in conjunction with the accompanying drawing, in which:

FIG. 1 illustrates a prior art M2M communications system in an IEEE 802.16 compliant communications system;

FIG. 2a illustrates an example communications system according to example embodiments described herein;

FIG. 2b illustrates a technique of using an identifier to identify signaling to a communications device(s) according to example embodiments described herein;

FIG. 3a illustrates an example flow diagram of operations in a transmitting device identifying a message by embedding an information sequence in a message payload used to generate an error check code according to example embodiments described herein;

FIG. 3b illustrates an example flow diagram of operations in a receiving device determining if a message includes an information sequence, wherein a transmitting device embeds the information sequence in a message payload used to generate an error check code according to example embodiments described herein;

FIG. 4a illustrates an example flow diagram of operations in a transmitting device identifying a message by modifying information in the message with an information sequence according to example embodiments described herein;

FIG. 4b illustrates an example flow diagram of operations in a receiving device determining if a message includes an information sequence, wherein a transmitting device includes the information sequence by modifying information in the message with the information sequence according to example embodiments described herein;

FIG. 5a illustrates an example technique for identifying a communications device(s) by a source communications device, wherein identifying information is used to calculate a CRC according to example embodiments described herein;

FIG. 5b illustrates an example technique for identifying a communications device(s) by a recipient communications device, wherein identifying information is used to calculate a CRC according to example embodiments described herein;

FIG. 6a illustrates an example technique for identifying a communications device(s) by a source communications device, wherein identifying information is combined with signaling information according to example embodiments described herein;

FIG. 6b illustrates an example technique for identifying a communications device(s) by a recipient communications device, wherein identifying information is combined with signaling information according to example embodiments described herein;

FIG. 7a illustrates an example technique for identifying a communications device(s) by a source communications device, wherein multiple identifying information sequences are used to calculate a CRC according to example embodiments described herein;

FIG. 7b illustrates an example technique for identifying a communications device(s) by a recipient communications device, wherein multiple identifying information sequences are used to calculate a CRC according to example embodiments described herein;

FIG. 8a illustrates an example combination technique for identifying a communications device(s) by a source communications device, wherein both CRC and payload are modified according to example embodiments described herein;

FIG. 8b illustrates an example combination technique for identifying a communications device(s) by a recipient communications device, wherein both CRC and payload are modified according to example embodiments described herein;

FIG. 9a illustrates an example technique for identifying a communications device(s) by a source communications device, wherein multiple identifying information sequences and payload partitioning are used to calculate a CRC according to example embodiments described herein;

FIG. 9b illustrates an example technique for identifying a communications device(s) by a recipient communications device, wherein multiple identifying information sequences and payload partitioning are used to calculate a CRC according to example embodiments described herein;

FIG. 10a illustrates an example technique for identifying a communications device(s) by a source communications device, wherein an indicator and a modified payload are used according to example embodiments described herein;

FIG. 10b illustrates an example flow diagram of communications device operations 750 for processing a received transmission according to example embodiments described herein;

FIG. 10c illustrates an example technique for identifying a communications device(s) by a source communications device, wherein an identifying information sequence and a payload is used to calculate a CRC, as well as an indicator are used according to example embodiments described herein;

FIG. 11a illustrates an example MAP architecture for the current IEEE 802.16m technical standards;

FIG. 11b illustrates an example MAP architecture modified with a second assignment A-MAP for a new identifier domain according to example embodiments described herein;

FIG. 11c illustrates an example technique at a source communications device for identifying a communications device(s) using a new identifier domain according to example embodiments described herein;

FIG. 11d illustrates an example technique at a recipient communications device for identifying a communications device(s) using a new identifier domain according to example embodiments described herein;

FIG. 12 illustrates an example technique at a source communications device for providing multiple level identifier information to a recipient communications device according to example embodiments described herein;

FIG. 13a illustrates a flow diagram of operations in a transmitting device providing multiple level identifier information to a receiving device according to example embodiments described herein;

FIG. 13b illustrates a flow diagram of operations in a receiving device as it receives multiple level identifier information from a transmitting device according to example embodiments described herein; and

FIG. 14 provides an example communications device according to example embodiments described herein.

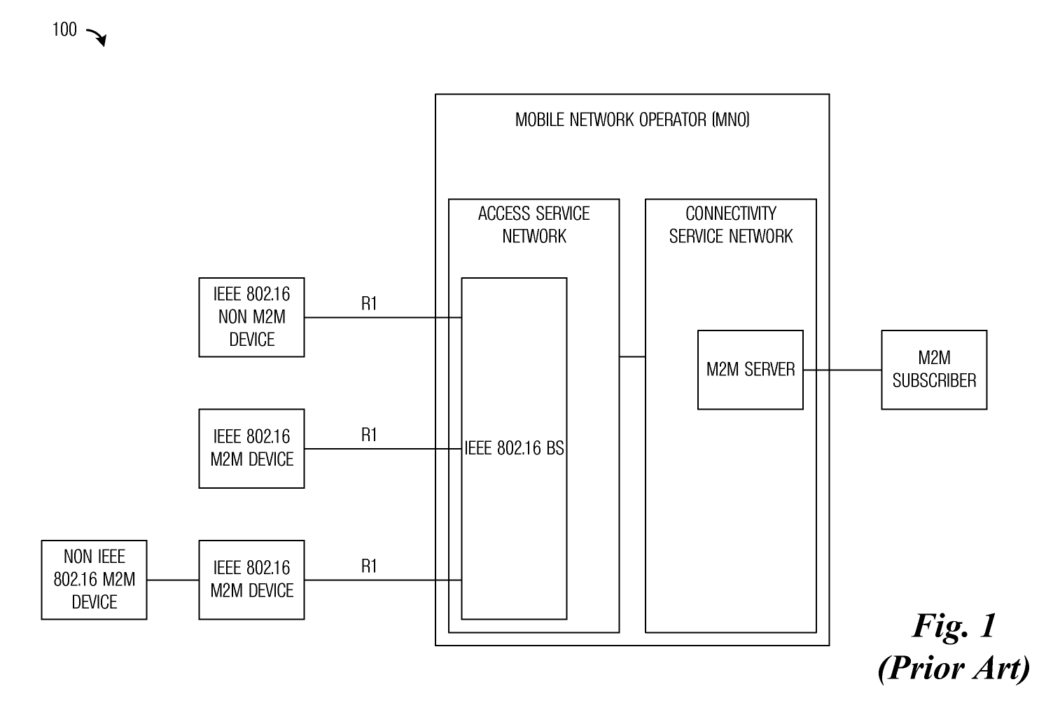

### DETAILED DESCRIPTION OF ILLUSTRATIVE EMBODIMENTS

The operating of the current example embodiments and the structure thereof are discussed in detail below. It should be appreciated, however, that the present disclosure provides many applicable inventive concepts that can be embodied in a wide variety of specific contexts. The specific embodiments discussed are merely illustrative of specific structures of the disclosure and ways to operate the disclosure, and do not limit the scope of the disclosure.

One embodiment of the disclosure relates to identifying devices in a communications system. For example, a transmitting device identifies a recipient by embedding an identifying sequence of the recipient in a message payload to be transmitted to the recipient to produce an augmented payload and generating an error check code from the augmented payload. The error check code now carries the identifying sequence of the recipient. The transmitting device transmits the message payload and the error check code. For example, a transmitting device identifies a recipient by modifying a message payload with an identifying sequence of the recipient to produce a modified payload and generating an error check code from the message payload. The transmitting device transmits the modified payload and the error check code.

The present disclosure will be described with respect to example embodiments in a specific context, namely a WiMAX communications system supporting M2M devices. The disclosure may also be applied, however, to other standards compliant communications systems that are supporting M2M devices, such as 3GPP LTE, 3GPP LTE-A, and the like, compliant communications systems that are supporting M2M devices. The disclosure may also be applied to non-standards compliant communications systems that are supporting M2M devices. The disclosure may also be applied to communications systems (standards compliant as well as non-standards compliant) that are not supporting M2M devices.

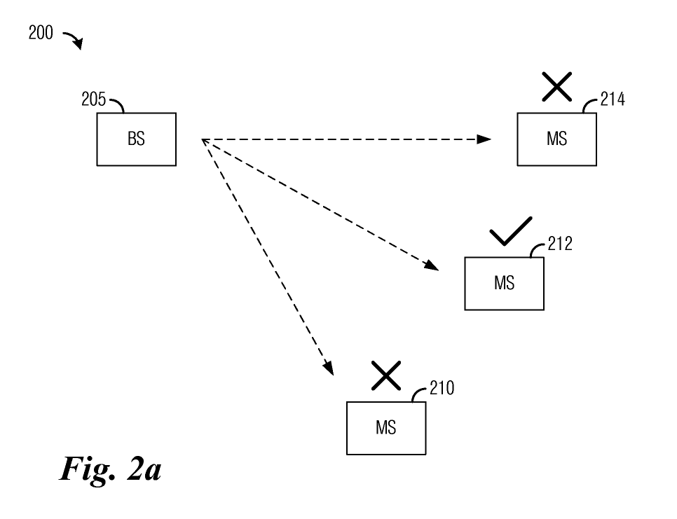

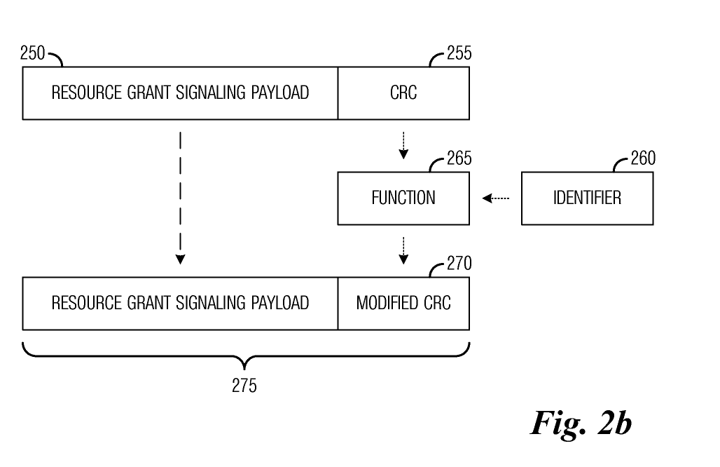

FIG. 2a illustrates a communications system 200. Communications system 200 includes a base station (BS) 205. A base station may also be commonly referred to as a controller, a communications controller, a NodeB, an evolved NodeB, and so on. BS 205 may communicate to one or more mobile stations (MS), such as MS 210, MS 212, and MS 214. A mobile station may also be commonly referred to as a terminal, a user, a communications device, a User Equipment, and so forth. While it is understood that communications systems may employ multiple BSs capable of communicating with a number of MSs, only one BS, and three MSs are illustrated for simplicity.

In M2M communications, a large (on the order of thousands and more) number of communications devices may have to be supported. For example, in an IEEE 802.16 compliant communications system supporting M2M, potentially more than 30000 communications devices in a single cell may need to be supported. Therefore, there may be a need to identify communications devices without incurring significant overhead.

In WiMAX compliant communications systems, using IEEE 802.16e and/or IEEE 802.16m air interface technologies), a 12-bit long device identifier referred to as a station identifier (STID) may be used in identifying communications devices. In 3GPP LTE compliant communications systems, a 16-bit long radio network temporary identifier (RNTI) may be used in identifying communications devices.

In both WiMAX and LTE compliant communications systems, a device identifier may be used to mask a cyclic redundancy check (CRC) of resource grant signaling (a MAP/A-MAP in WiMAX and a physical downlink control channel (PDCCH) in LTE) so that when a communications device receives the signaling, the communications device can check whether it is the intended recipient of the signaling.

FIG. 2b illustrates a technique of using an identifier to identify signaling to a communications device(s). As shown in FIG. 2b, a resource grant signaling payload 250 containing signaling intended for a communications device and its associated CRC 255 is to be transmitted (e.g., broadcast) by a source communications device to the communications device. Since resource grant signaling payload 250 and CRC 255 is broadcast, multiple communications devices may receive the transmission. It may be up to the receiving communications devices to determine if they are truly the intended recipient of the transmission.

In order to address resource grant signaling payload 250 and CRC 255 to a specific recipient(s), an identifier 260 may be applied to CRC 255 using a function 265. Identifier 260 may be known by the specific recipient(s). As an example, identifier 260 may be a unique identifier of the specific recipient(s). Typically, function 265 is typically a masking function, i.e., a logical exclusive-OR (XOR) function, however, other functions, such as logical exclusive-NOR (XNOR), may be used. Function 265 applies identifier 260 to CRC 255 and produces a modified CRC 270. Resource grant signaling payload 250 and modified CRC 270 (collectively referred to as transmission 275) may be transmitted (broadcast).

At a recipient, the recipient may apply its own identifier to modified CRC 270 and if the recipient is an intended recipient of transmission 275, then an output of modified CRC 270 applied with the identifier of the recipient will produce a CRC that is correct for resource grant signaling payload 250. As an example, the recipient may test to determine if is the intended recipient of the transmission by applying the output of modified CRC 270 applied with the identifier of the recipient to resource grant signaling payload 250 and if the test result confirms that the output is the CRC for resource grant signaling payload 250, then the recipient is indeed the intended recipient of transmission 275.

According to an example embodiment, the transmitting device may identify the recipient by embedding an information sequence in a message payload used to generate an error check code. According to an alternative example embodiment, the transmitting device may identify the recipient by modifying information in a message with an information sequence. The transmitting device may also combine embedding an information sequence and modifying information to identify the recipient.

Although the discussion focuses on using an information sequence embedded in a message to identify an intended recipient (or group of intended recipients) of the message, the embedding of the information sequence may be used for a variety of other purposes. As an example, the embedding of the information sequence in a message may be used to indicate or identify a message class or a message type of the message. The embedding of the information sequence in a message may also be used to indicate or identify a source of the message. Therefore, the discussion of the use of the embedding of an information sequence in a message to identify an intended recipient should not be construed as being limiting to either the scope or the spirit of the example embodiments.

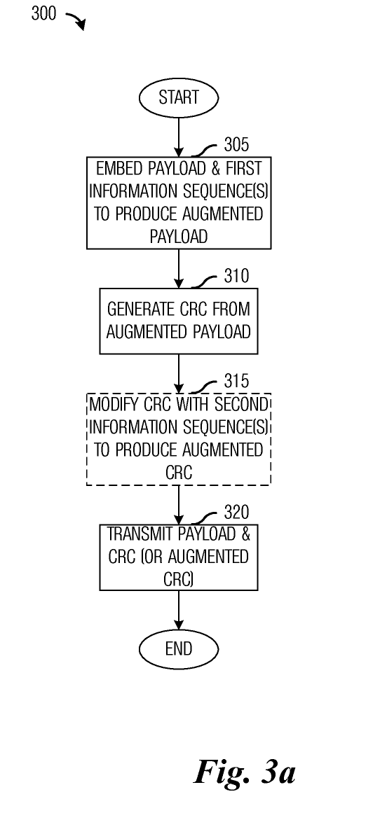

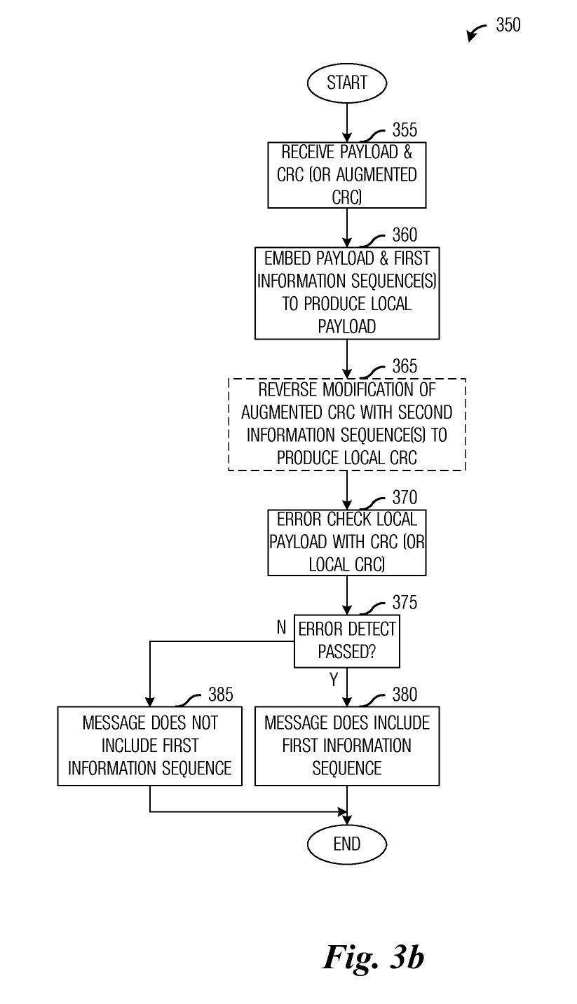

FIG. 3a illustrates a flow diagram of operations 300 in a transmitting device identifying a message by embedding an information sequence in a message payload used to generate an error check code. Operations 300 may be indicative of operations occurring in a transmitting device, such as BS 205, as it identifies a message by embedding an information sequence in a message payload used to generate an error check code for the message payload.

Operations 300 may begin with the transmitting device embedding a first information sequence or a plurality of first information sequences in a message payload to produce an augmented payload (block 305). As an example, the first information sequence may be associated with an intended recipient of the message, wherein the first information sequence may be an identifier of the intended recipient, such as a STID or a RNTI of the intended recipient. As another example, a plurality of first information sequences may be used, with one of the first information sequences being a group identifier of the intended recipient, another of the first information sequences being a type identifier of the intended recipient, and yet another of the first information sequences being a subgroup identifier of the intended recipient, et cetera. As another example, the first information sequence may be associated with a type or class of the message, or the first information sequence may be associated with the transmitting device. In general, the first information sequence may be associated with a value of a characteristic or characteristics that is to be transmitted in a message.

According to an example embodiment, embedding the first information sequence in the message payload may include appending the first information sequence to either a beginning or an end of the message payload. Alternatively, the first information sequence may be inserted in its entirety somewhere within the message payload. Alternatively, the first information sequence may be interleaved with the message payload. Alternatively, a combination of appending, inserting, or interleaving may be used to embed the first information sequence in the message payload.

The transmitting device may generate an error check code, such as a cyclic redundancy check (CRC) code from the augmented payload (block 310). As an example, the transmitting device may provide the augmented payload as an input to a CRC code generator that provides as an output the error check code. Since the error check code is generated from the augmented payload, which comprises the original payload with the first information sequence embedded in it, the error check code may be said to be derived from the first information sequence As an example, the first information sequence may not be immediately evident in the error check code, however, it may be possible to recover the first information sequence by applying an inverse of a function (or a corresponding function that is associated with the function) used to generate the error check code.

As another example, consider an original payload that is in the form of a bit sequence bit_sequence_1, an information sequence that is in the form of a bit sequence bit_sequence_2. Then, the augmented payload may be expressed as bit_sequence_3. Then, a CRC code may be generated by providing the augmented payload (bit_sequence_3) to the CRC code generator. Since the CRC code is generated from the augmented payload, which comprises the original payload and the information sequence, the CRC code may be said to be derived from the information sequence.

Optionally, the transmitting device may modify the error check code by providing the error check code and a second information sequence or a plurality of second information sequences to a function to produce an augmented error check code (block 315). As an example, the function may be a binary function having two inputs, e.g., the error check code and the second information sequence or the plurality of second information sequences, and produces an output, e.g., an augmented error check code. As an example, the function may be a binary exclusive-OR function or a binary exclusive-NOR function. The second information sequence may also be used to identify the intended recipient of the message. The second information sequence may also be used to identify a class or a type of the message, identify the transmitting device, identify a value of a characteristic or characteristics, and the like.

The transmitting device may transmit the message payload and the error check code (or the augmented error check code) (block 320). As an example, the transmitting device may broadcast the message payload and the error check code (or the augmented error check code).

FIG. 3b illustrates a flow diagram of operations 350 in a receiving device determining if a message includes an information sequence, wherein a transmitting device embeds the information sequence in a message payload used to generate an error check code. Operations 350 may be indicative of operations occurring in a receiving device, such as a MS 210, MS 212, and MS 214, as the receiving device determines if the message includes the information sequence.

Operations 350 may begin with the receiving device receiving a message including a message payload and an error check code from the transmitting device (block 355). Depending on operations of the transmitting device, the error check code may be an augmented error check code or an un-augmented error check code.

The receiving device may embed a first information sequence or a plurality of first information sequences in the message payload to produce a local payload (block 360). According to an example embodiment, embedding the first information sequence in the message payload may include appending the first information sequence to either a beginning or an end of the message payload. Alternatively, the first information sequence may be inserted in its entirety somewhere within the message payload. Alternatively, the first information sequence may be interleaved with the message payload. Alternatively, a combination of appending, inserting, or interleaving may be used to embed the first information sequence in the message payload. It is noted that the embedding performed by the receiving device may be the same as the embedding performed by the transmitting device.

Optionally, the receiving device may reverse the modification of the augmented error check code by providing the augmented error check code and a second information sequence or a plurality of second information sequences to a function to produce a local error check code (block 365). It is noted that the function used by the receiving device may be the same as a function used by the transmitting device or is a corresponding function to the function use by the transmitting device. As an example, the function may be a binary exclusive-OR function or a binary exclusive-NOR function.

The receiving device may perform an error check on the local payload with the error check code (or the local error check code) (block 370). According to an example embodiment, the receiving device may generate a local error check code from the local payload and then compare the local error check code and the error check code. If they are the same, then the error check passes. If they are not the same, then the error check fails. According to an alternative example embodiment, the receiving device may provide the error check code and the local payload to an error check function that provides an indication of whether or not the error check code detected an error in the local payload. If the indication provided by the error check function indicates that it detected an error, then the error check fails. If the indication provided by the error check function indicates that it did not detect an error, then the error check passes.

The receiving device may perform a check to determine if the error check passes or fails (block 375). If the error check passes, then the receiving device may determine that the message does include the information sequence, e.g., the first information sequence (as well as optionally the second information sequence) (block 380). If the error check fails, then the receiving device may determine that the message does not include the information sequence, e.g., the first information sequence (as well as optionally the second information sequence) (block 385). As an example, if the first information sequence is an identifier associated with the receiving device, and the receiving device determines that the message does include the first information sequence, then the receiving device may determine that it is the intended recipient of the message.

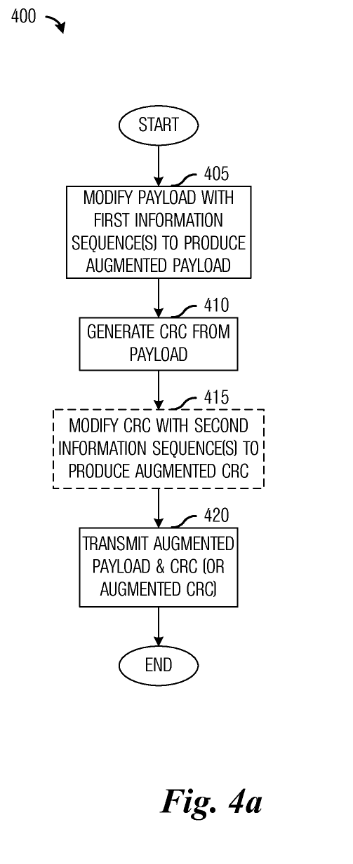

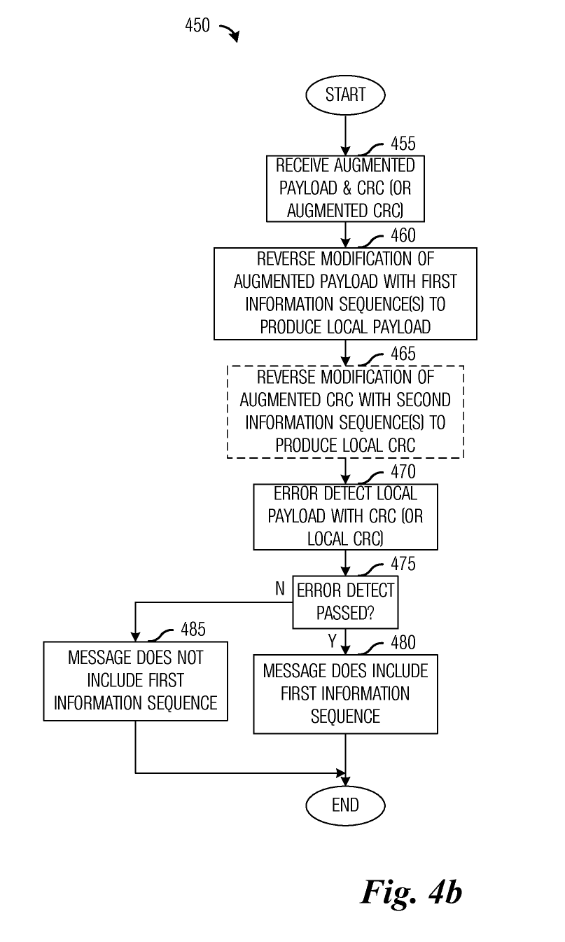

FIG. 4a illustrates a flow diagram of operations 400 in a transmitting device identifying a message by modifying information in the message with an information sequence. Operations 400 may be indicative of operations occurring in a transmitting device, such as BS 205, as it identifies a message by modifying information in the message with the information sequence.

Operations 400 may begin with the transmitting device modifying a message payload by providing the message payload and a first information sequence or a plurality of second information sequences to a first function to produce an augmented payload (block 405). The augmented payload may then include the first information sequence or a formulation of the first information sequence, wherein the formulation is in accordance with the first function. As an example, the first function may be a binary function having two inputs, e.g., the message payload and the first information sequence or the plurality of first information sequences, and produces an output, e.g., an augmented payload. As an example, the first function may be a binary exclusive-OR function or a binary exclusive-NOR function.

The transmitting device may generate an error check code, such as a cyclic redundancy check (CRC) code from the message payload (block 410). As an example, the transmitting device may provide the message payload as an input to a CRC code generator that provides as an output the error check code.

Optionally, the transmitting device may modify the error check code by providing the error check code and a second information sequence or a plurality of second information sequences to a second function to produce an augmented error check code (block 315). As an example, the second function may be a binary function having two inputs, e.g., the error check code and the second information sequence or the plurality of second information sequences, and produces an output, e.g., an augmented error check code. As an example, the second function may be a binary exclusive-OR function or a binary exclusive-NOR function. It is noted that the first function and the second function may be the same functions or they may be different functions.

The transmitting device may transmit the augmented payload and the error check code (or the augmented error check code) (block 420). As an example, the transmitting device may broadcast the augmented payload and the error check code (or the augmented error check code).

FIG. 4b illustrates a flow diagram of operations 450 in a receiving device determining if a message includes an information sequence, wherein a transmitting device includes the information sequence in the message by modifying information in the message with the information sequence. Operations 450 may be indicative of operations occurring in a receiving device, such as a MS 210, MS 212, and MS 214, as the receiving device determines if the message includes the information sequence.

Operations 450 may begin with the receiving device receiving a message including an augmented payload and an error check code from the transmitting device (block 455). Depending on operations of the transmitting device, the error check code may be an augmented error check code or an un-augmented error check code.

The receiving device may reverse the modification of the augmented payload by providing the augmented payload and a first information sequence or a plurality of first information sequences to a first function to produce a local payload (block 460). It is noted that the first function used by the receiving device may be the same as a function used by the transmitting device or is a corresponding function to the function use by the transmitting device. As an example, the first function may be a binary exclusive-OR function or a binary exclusive-NOR function.

Optionally, the receiving device may reverse the modification of the augmented error check code by providing the augmented error check code and a second information sequence or a plurality of second information sequences to a second function to produce a local error check code (block 465). It is noted that the second function used by the receiving device may be the same as a function used by the transmitting device or is a corresponding function to the function use by the transmitting device. As an example, the second function may be a binary exclusive-OR function or a binary exclusive-NOR function. It is noted that the first function and the second function may be the same functions or they may be different functions.

The receiving device may perform an error check on the local payload with the error check code (or the local error check code) (block 470). According to an example embodiment, the receiving device may generate a test error check code from the local payload and then compare the test error check code and the error check code. If they are the same, then the error check passes. If they are not the same, then the error check fails. According to an alternative example embodiment, the receiving device may provide the error check code and the local payload to an error check function that provides an indication of whether or not the error check code detected an error in the local payload. If the indication provided by the error check function indicates that it detected an error, then the error check fails. If the indication provided by the error check function indicates that it did not detect an error, then the error check passes.

The receiving device may perform a check to determine if the error check passes or fails (block 475). If the error check passes, then the receiving device may determine that the message does include the information sequence, e.g., the first information sequence (as well as optionally the second information sequence) (block 480). If the error check fails, then the receiving device may determine that the message does not include the information sequence, e.g., the first information sequence (as well as optionally the second information sequence) (block 485). As an example, if the first information sequence is an identifier associated with the receiving device, and the receiving device determines that the message does include the first information sequence, then the receiving device may determine that it is the intended recipient of the message.

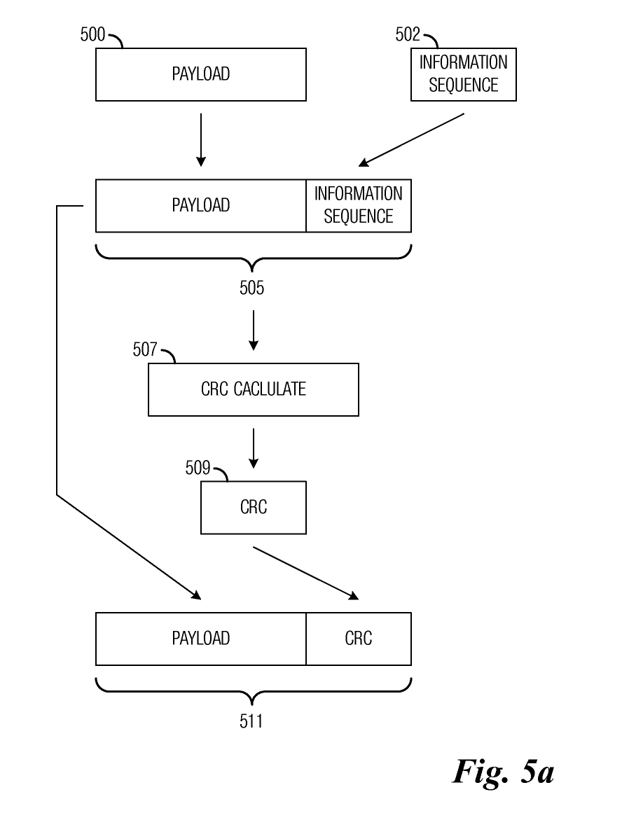

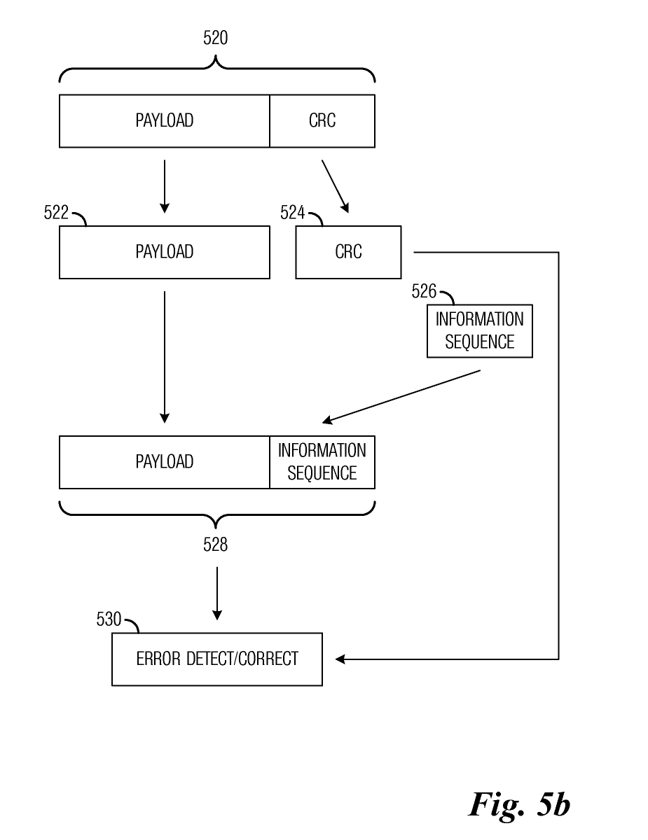

FIG. 5a illustrates a technique for identifying a communications device(s) by a transmitting device, wherein identifying information is used to calculate a CRC. As shown in FIG. 5a, a payload 500 comprising the signaling information may be identified by an information sequence 502, e.g., the identifier. Information sequence 502 may be embedded in payload 500 to form a CRC calculating payload 505, which may be provided to a CRC calculate unit 507 to produce a CRC 509. In an example embodiment, information sequence 502 may be appended to payload 500 to form CRC calculating payload 505. It is noted that CRC calculating payload may also be referred to as an augmented payload. Payload 500 and CRC 509 (collectively referred to as transmission 511) may then be transmitted.

Although the discussion presented herein focuses on information sequence 502 being identifying information, e.g., the identifier, the example embodiments presented herein may be operable with any type of information. Information sequence 502 may comprise security information, security key, processing information, coordinating information, configuring information, and so forth. Therefore, the focus on identifying information should not be construed as being limiting to either the scope or the spirit of the embodiments. When information other than identifying information are used as information sequences, the information sequences are said to be embedded in a transmission made or received by a communications device.

According to an example embodiment, information sequence 502 may be appended to an end of payload 500 (however, information sequence may be placed in any location in payload 500, including inside payload 500). In general, any possible embedding of information sequence 502 in payload 500 may be possible as long as both transmitting device and receiving devices know the arrangement.

FIG. 5b illustrates a technique for identifying a communications device(s) by a receiving device, wherein identifying information is used to calculate a CRC. As shown in FIG. 5b, a transmission 520 is received by the receiving device. Transmission 520 comprises a payload 522 and a CRC 524. The receiving device embeds its information sequence 526 (e.g., its identifier, or any other type of information) in payload 522 in an arrangement known by both a transmitting device of transmission 520 and itself. In an example embodiment, the receiving device appends its information sequence 526 with payload 522. Collectively, payload 522 and information sequence 526 may be referred to as a local augmented payload, as well as a CRC calculating payload 528, and may be applied to an error detect and correct unit 530 along with CRC 524. If CRC 524 is the correct CRC for CRC calculating payload 528, then the receiving device is the intended recipient of transmission 520 and payload 522 is intended for the receiving device. If CRC 524 is not the correct CRC for CRC calculating payload 528, then the receiving device is not the intended recipient of transmission 520 and payload 522 is not intended for the receiving device.

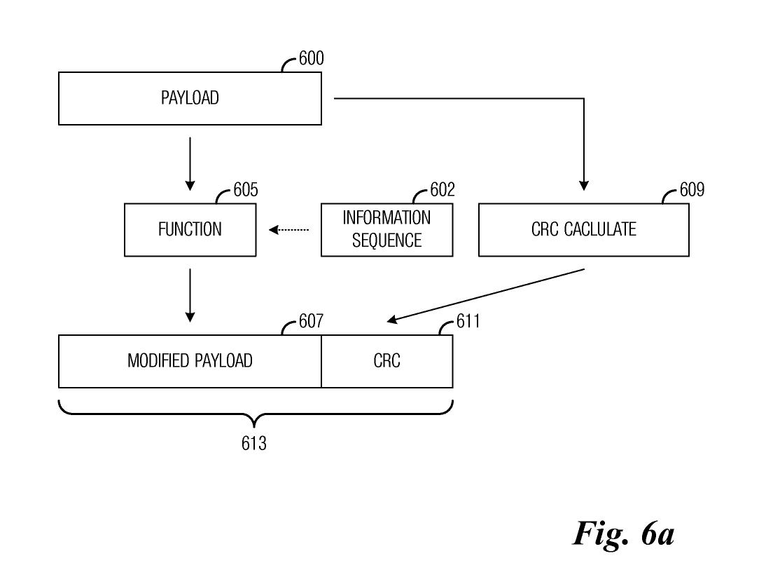

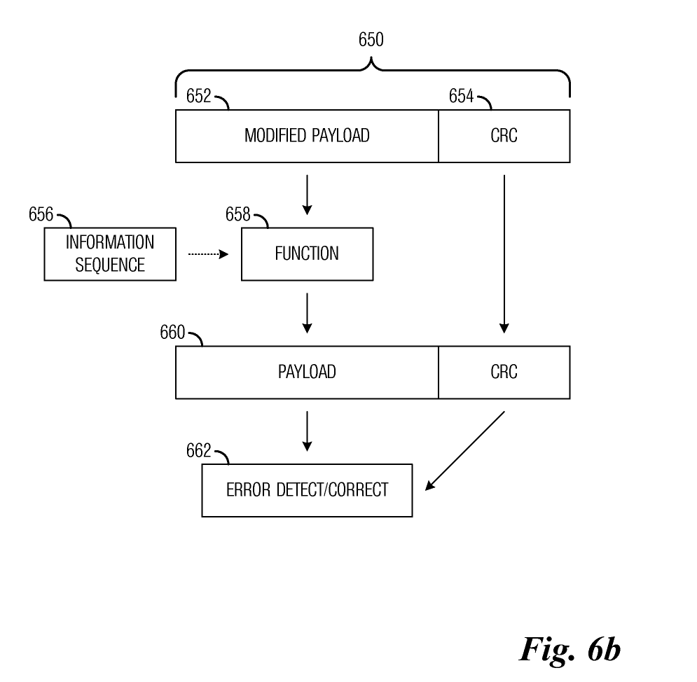

FIG. 6a illustrates a technique for identifying a communications device(s) by a transmitting device, wherein identifying information is combined with signaling information. A payload 600 comprising the signaling information may be combined with identifying information (or any other information), e.g., an information sequence 602, through a function 605. Function 605 may combine information sequence 602 and any part or whole of payload 600 in any possible arrangement that is known by both transmitting device and receiving device to produce a modified payload 607. In an example embodiment, output of function 605 may also be referred to as an augmented payload. Examples of function 605 include an exclusive-OR function and an exclusive-NOR function.

Modified payload 607 may be a result of the combination of information sequence 602 and payload 600 by function 605. A CRC calculate unit 609 may compute a CRC 611 from payload 600. Modified payload 607 and CRC 611, which may be referred to collectively as transmission 613, may be transmitted to the receiving device.

FIG. 6b illustrates a technique for identifying a communications device(s) by a receiving device, wherein identifying information is combined with signaling information. A transmission 650 comprising an augmented payload 652 and a CRC 654 may be received by the receiving device. The receiving device may apply its identifying information (or any other information), e.g., an information sequence 656, to any part or whole of modified payload 652 through a function 658 to create a local payload 660.

Local payload 660 and CRC 654 may be provided to an error detect and correct unit 662. If CRC 654 is the correct for local payload 660, then the receiving device may be the intended recipient of transmission 650 and payload 660 is intended for the receiving device. If CRC 654 is not the correct for local payload 660, then the receiving device may not be the intended recipient of transmission 650 and payload 660 may not be intended for the receiving device.

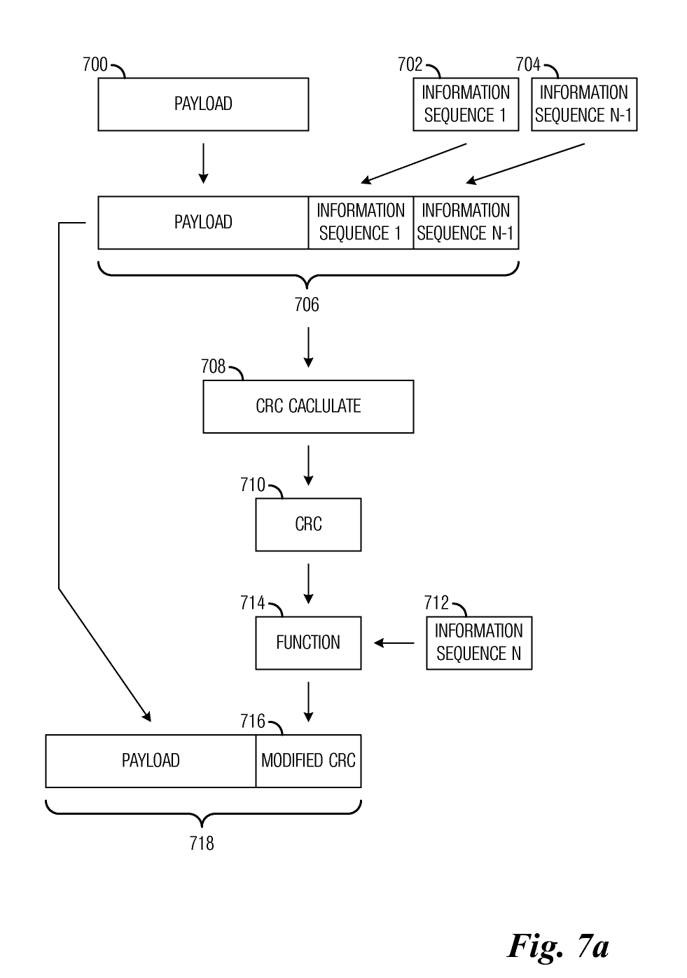

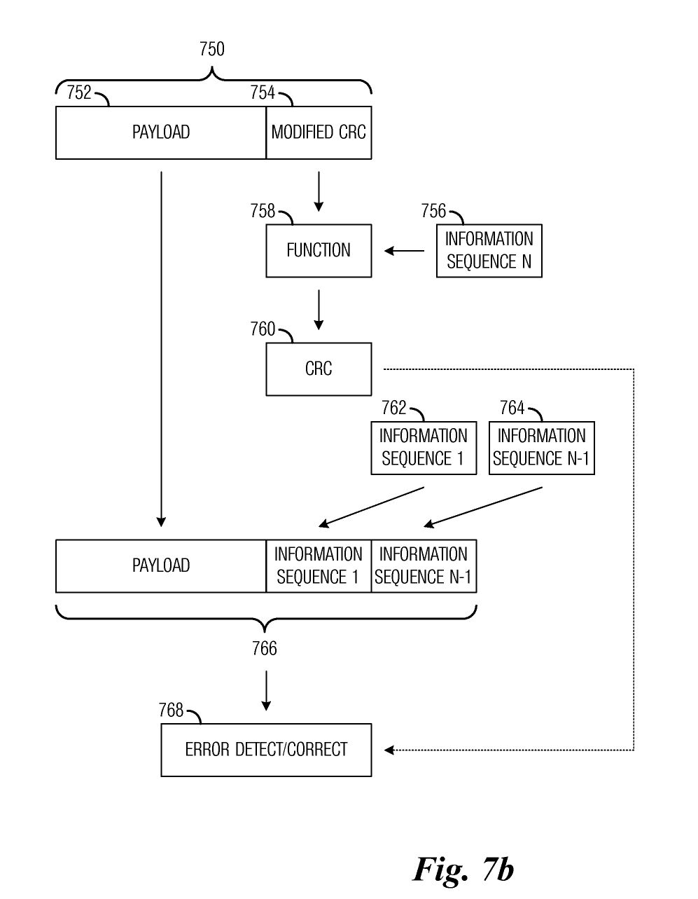

FIG. 7a illustrates a technique for identifying a communications device(s) by a transmitting device, wherein multiple identifying information sequences are supported. A payload 700 may be embedded with multiple information sequences, such as information sequence 1 702 and information sequence N-1 704. In an example embodiment, payload 700 may be appended with multiple information sequences. According to an example embodiment, the multiple information sequences may be appended, concatenated, and/or combined with payload 700 in any possible combination as long as both the transmitting device and a receiving device know how the payload 700 and the multiple information sequences are embedded.

Collectively payload 770 and the multiple information sequences may be referred to as CRC calculating payload 706. In an example embodiment, payload 770 and the multiple information sequences may be referred to as an augmented payload. CRC calculating payload 706 may be used to generate a CRC 710 using CRC calculate unit 708. Another information sequence, e.g., information sequence N 712, may be applied to CRC 710 with function 714 to modify CRC 710. Function 714 may be a binary function, such as an XOR or XNOR function. Function 714 may utilize information sequence N 712 and CRC 710 to produce a modified CRC 716. In an example embodiment, modified CRC 716 may be referred to as an augmented CRC.

Payload 700 and modified CRC 716 may be referred to collectively as transmission 718 and may be transmitted to the receiving device. In general, N-1 information sequences may be embedded in a payload to produce a CRC calculating payload and an N-th information sequence may be combined with a CRC produced from the CRC calculating payload. However, other combinations are possible, as an example, several information sequences may be embedded in a payload to produce a CRC calculating payload and several information sequences may be combined with a CRC produced from the CRC calculating payload to produce an augmented CRC.

FIG. 7b illustrates a technique for identifying a communications device(s) by a receiving device, wherein multiple identifying information sequences are supported. A transmission 750 comprising a payload 752 and a modified CRC 754 may be received by the receiving device. In an example embodiment, modified CRC 754 may also be referred to as an augmented CRC. The receiving device may apply an N-th information sequence 756 to modified CRC 754 using function 758 to produce a CRC 760, which may be referred to as a local CRC. According to an example embodiment, function 758 may be a binary function, such as an XOR or XNOR.

Additionally, the receiving device may embed (concatenate, insert, and/or append, for example) N-1 information sequences (such as information sequence 1 762 and information sequence N-1 764) in payload 752 to produce a CRC calculating payload 766, which may be referred to as a local payload. An error detect and correct unit 768 may check CRC calculating payload 766 with CRC 760 to determine if transmission 750 was intended for the receiving device. If CRC 760 is the correct for CRC calculating payload 766, then the receiving device may be the intended recipient of transmission 750 and payload 752 is intended for the receiving device. If CRC 760 is not the correct for CRC calculating payload 766, then the receiving device may not be the intended recipient of transmission 750 and payload 752 may not be intended for the receiving device.

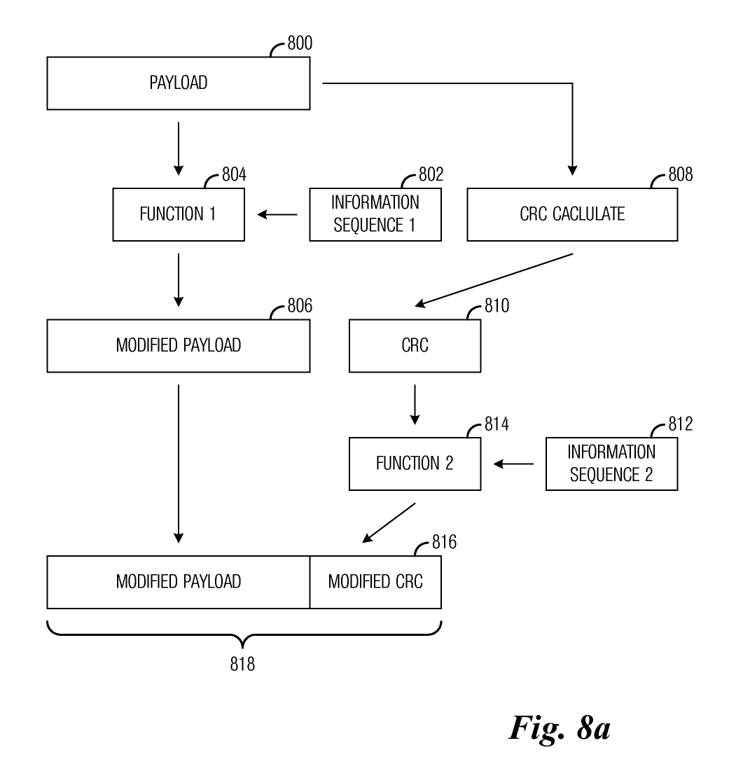

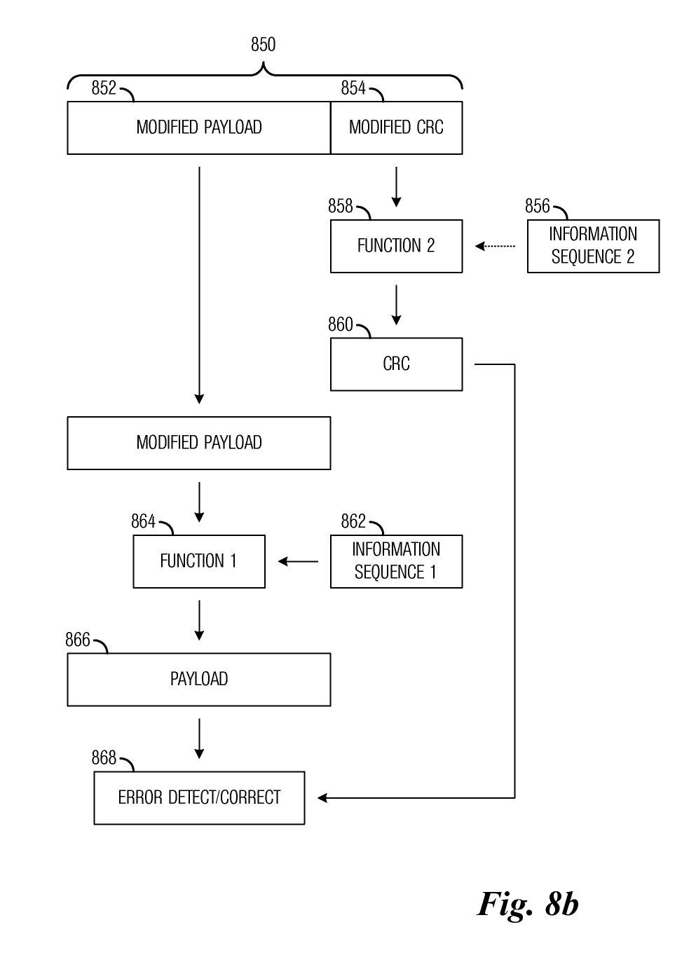

FIG. 8a illustrates a combination technique for identifying a communications device(s) by a transmitting device, wherein both CRC and payload are modified. A payload 800 may be combined with a first information sequence 802 using a first function (e.g., function 1) 804 to produce a modified payload 806, also referred to as augmented payload. According to an example embodiment, payload 800 and first information sequence 802 may be combined in any possible arrangement through first function 804 as long as both the transmitting device and a receiving device know the arrangement. As an example, first function 802 may be a XOR or XNOR function.

Payload 800 may be used to calculate a CRC using a CRC calculate unit 808 to produce a CRC 810, which may be modified with a second information sequence 812 using a second function (e.g., function 2) 814, thereby producing a modified CRC 816, also referred to as an augmented CRC. Collectively, modified payload 808 and modified CRC 816 may be referred to as transmission 818. Second function 814 may be a XOR or XNOR function. It is noted that first function 804 and second function 814 may be the same function or different functions.

FIG. 8b illustrates a combination technique for identifying a communications device(s) by a receiving device, wherein both CRC and payload are modified. A transmission 850 comprising a modified payload 852 and a modified CRC 854 may be received by the receiving device. The receiving device may apply a second information sequence 856 to modified CRC 854 using a second function 858 to produce a CRC 860, also referred to as a local CRC. According to an example embodiment, second function 858 may be any binary function, such as a XOR or XNOR function.

A first information sequence 862 may be applied to modified payload 852 using a first function 864 to produce payload 866, also referred to as a local payload. According to an example embodiment, modified payload 852 and first information sequence 862 may be combined through first function 864 in an arrangement that is consistent with an arrangement used by the source communications device. As an example, first function 864 may be a XOR or XNOR function.

The recipient communications device may check payload 866 with CRC 860 using an error detect and correct unit 868. If payload 866 checks with CRC 860, then transmission 850 may be intended for the receiving device. If payload 866 does not check with CRC 860, then transmission 850 may not be intended for the receiving device.

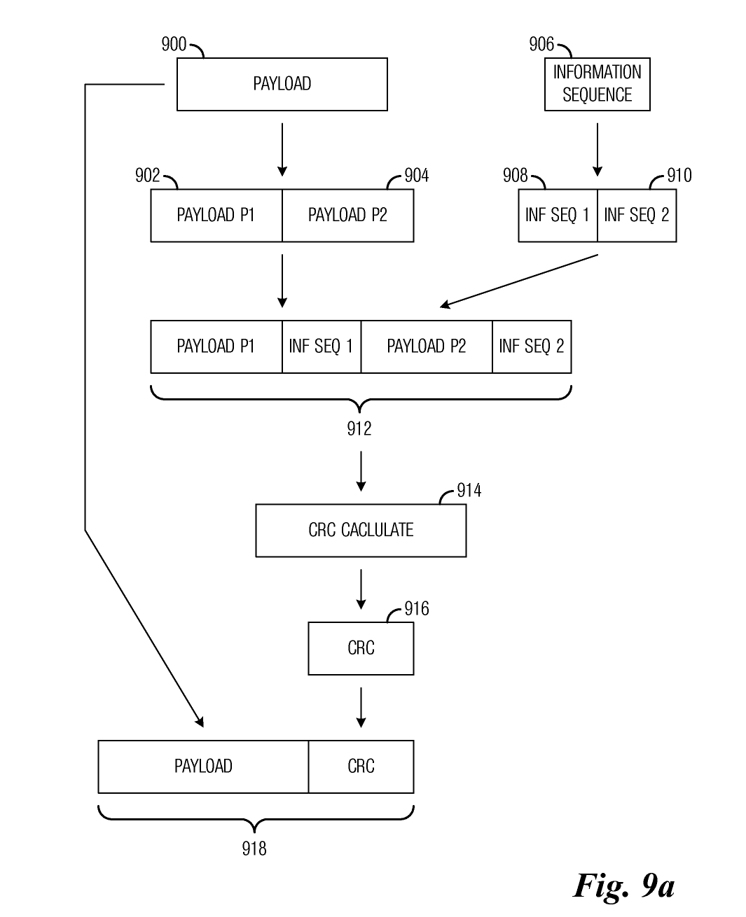

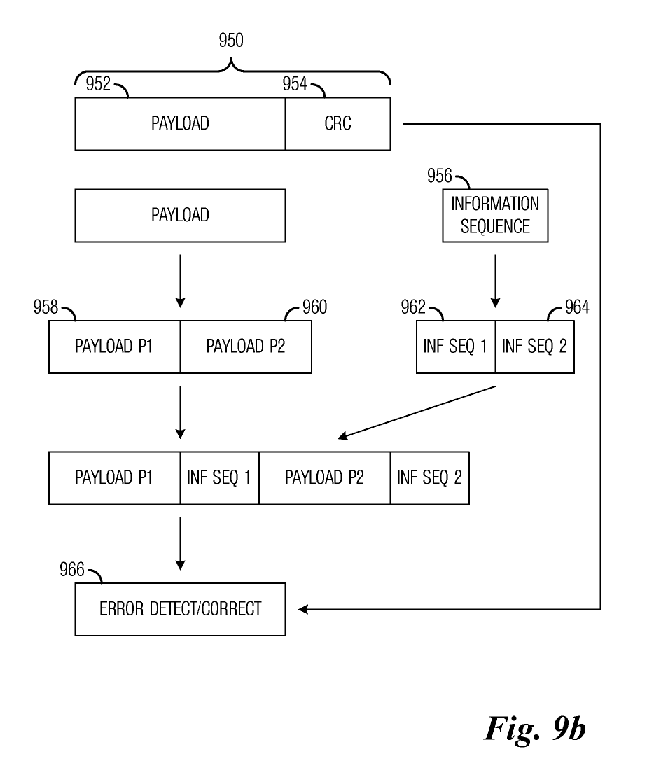

FIG. 9a illustrates a technique for identifying a communications device(s) by a transmitting device, wherein identifying information and payload partitioning are used to calculate a CRC. As shown in FIG. 9a, a payload 900 comprising the signaling information may include multiple payloads, e.g., payload p1 902 and payload p2 904. Similarly, an information sequence 906 may include multiple information sequences, e.g., information sequence 1 908 and information sequence 2 910. Payload p1 902 and payload p2 904 may be identified by embedding information sequence 1 908 and information sequence 2 910, e.g., identifying sequence 906, into payload p1 902 and payload p2 904. As shown in FIG. 9a, payload p1 902 and payload p2 904 and information sequence 1 908 and information sequence 2 910 may be interleaved, however, other ways of embedding may be possible, such as appending, interleaving at different granularities, concatenating, and the like, for example. Payload 900 and information sequence 906 may be combined to form a CRC calculating payload 912, which may be provided to a CRC calculate unit 914 to produce a CRC 916. In an example embodiment, CRC calculating payload 912 may be referred to as an augmented payload. Payload 900 and CRC 916 (collectively referred to as transmission 918) may then be transmitted.

FIG. 9b illustrates a technique for identifying a communications device(s) by a receiving device, wherein identifying information is used to calculate a CRC. As shown in FIG. 9b, a transmission 950 is received by the receiving device. Transmission 950 comprises a payload 952 and a CRC 954. The receiving device combines its information sequence 956 (e.g., its identifier, or any other type of information) with payload 952 in an arrangement known by both a transmitting device of transmission 900 and itself. As shown in FIG. 9b, payload 952 includes multiple payloads, e.g., payload P1 958 and payload P2 960, while information sequence 956 includes information sequence 1 962 and information sequence 2 964. The receiving device may embed information sequence 1 962 and information sequence 2 964 into payload P1 958 and payload P2 960, as shown in FIG. 9b, for example.

Collectively, payload P1 958 and payload P2 960 and information sequence 1 962 and information sequence 2 964 may be referred to as a CRC calculating payload and may be applied to an error detect and correct unit 966 along with CRC 954. In an example embodiment, payload P1 958 and payload P2 960 and information sequence 1 962 and information sequence 2 964 may be referred to as an augmented payload. If CRC 954 is the correct CRC for the CRC calculating payload, then the receiving device may be the intended recipient of transmission 520 and payload 522 may be intended for the receiving device. If CRC 954 is not the correct CRC for the CRC calculating payload, then the receiving device may not be the intended recipient of transmission 520 and payload 522 may not be intended for the receiving device.

According to an example embodiment, an indicator may be included in a transmission to indicate if the payload has been modified or otherwise changed using an information sequence to address the transmission to a communications device(s). The indicator may be a single bit indicator or the indicator may be a multi-bit indicator.

In general, an indicator may be inserted in a transmission to indicate that the payload is combined with an information sequence or an information sequence is embedded in the payload for CRC generation. The indicator may a parameter that is one or more bits long or a type of signaling, message, and/or data package. As an example, if the indicator's value is one, then the indicator indicates that the payload is combined with an information sequence or an information sequence is embedded in the payload for CRC generation, while if the indicator's value is zero, then the indicator indicates that the payload is not combined with an information sequence or an information sequence is not embedded in the payload for CRC generation.

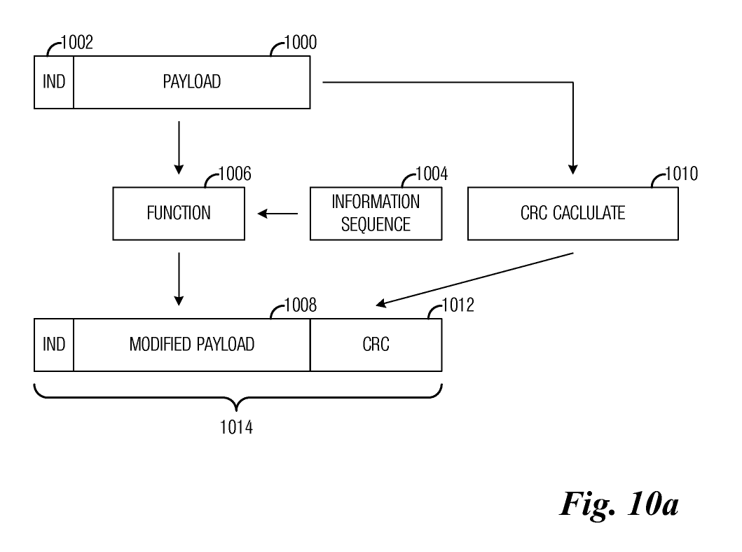

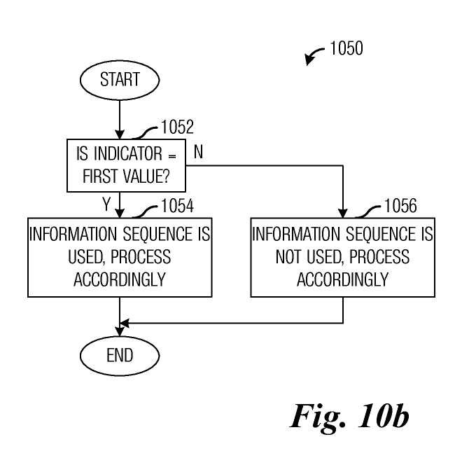

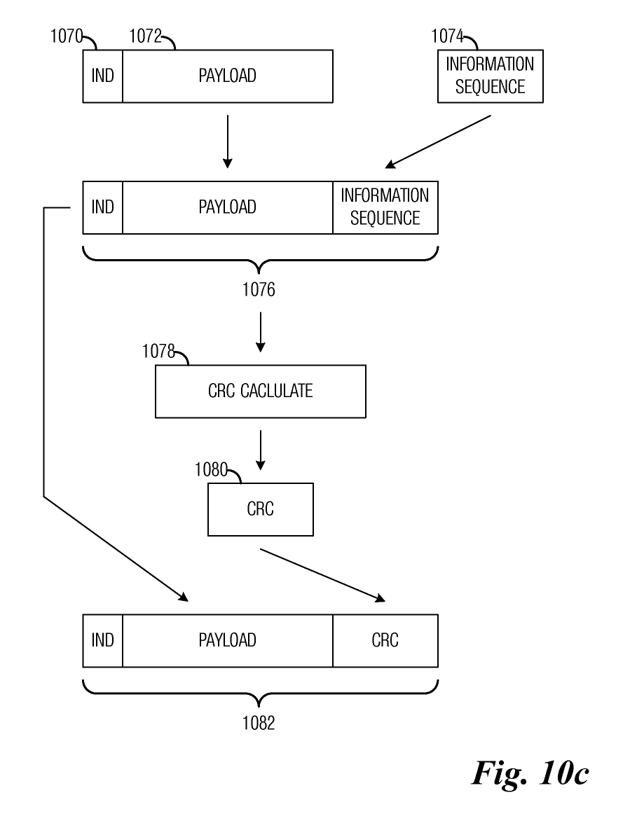

FIG. 10a illustrates a diagram of a technique for identifying a communications device(s) by a transmitting device, wherein an indicator is used. A payload 1000 may be associated with an indicator 1002 that may indicate if the payload or an associated CRC has been modified, i.e., addressed to a communications device(s). If payload 1000 is to be addressed, an information sequence 1004 may be combined with payload 1000 with function 1006, which may specify any possible combination of payload 1000 with information sequence 1004, to form a modified payload 1008.

Payload 1000 may also be provided to a CRC calculate unit 1010 to calculate a CRC 1012. Indicator 1002, modified payload 1008, and CRC 1012 may collectively be referred to as transmission 1014 and may be transmitted to the communications device(s).

FIG. 10b illustrates a flow diagram of communications device operations 1050 for processing a received transmission. Communications device operations 1050 may include checking the received transmission for a value of an indicator in the received transmission (block 1052). If the indicator is equal to a first value, e.g., a value indicating that the transmission has been addressed to a communications device(s), then the transmission may be processed according to a technique consistent with processing a transmission that has been address (block 1054). If the indicator is not equal to the first value, then the transmission has not been address to the communications device(s) and the transmission may be processed using a technique applicable to transmissions that have not been address to the communications device(s) (block 1056).

FIG. 10c illustrates a technique for identifying a communications device(s) by a transmitting device, wherein an indicator is used. An indicator 1070 may be associated with a payload 1072. An information sequence 1074 may be embedded in indicator 1070 and payload 1072 in some particular fashion that is known by both the transmitting device and a receiving device. Collectively, indicator 1070, payload 1072, and information sequence 1074 may be referred to as a CRC calculating payload 1076. In an example embodiment, CRC calculating payload 1076 may also be referred to as an augmented payload.

CRC calculating payload 1076 may be provided to a CRC calculate unit 1078 to calculate a CRC 1080. Indicator 1070, payload 1072, and CRC 1080 may be collectively referred to as transmission 1082.

It may be possible to set a type in a signaling, message, and/or data package as a value to show that a transmission has been addressed to a communications device(s). For example, in IEEE 802.16m, there are several types of A-A-MAP, it is possible to set the value of a type parameter in A-A-MAP to a special value that can indicate it is a payload masked A-A-MAP. As an example, the value of type parameter can be set to 0b1101 to indicate that the payload has been masked.

The above presented techniques may be used in wireless communications systems, such as WiMAX, 3GPP LTE, LTE-Advanced, HSPA, and the like, communications systems. It may be used for identifying multiple terminals in these communications systems, or convey more information. For example, in a M2M capable communications system, M2M devices may be grouped in different groups according to services, subscribers, or other characteristics. To identify the M2M devices with grouping characteristic, there are normally two approaches:

A first approach may use the setting of a second level identifier to identify the devices. Therefore, a first level identifier may be used to identify the group, while the second level identifier identifies the devices in the group identified by the first level identifier. The first level identifier may be referred to as a group identifier, while the second level identifier may be referred to as a device identifier. If a device belongs to multiple groups, then multiple group identifiers and device identifiers may be allocated to the device.

A second approach may use multiple, e.g., two, types of identifiers (e.g., a group identifier and a device identifier) are on the same level. However, a device's device identifier may be linked to a group's group identifier if the device belongs to the group.

Therefore, referencing the techniques presented above, it may be possible to place a device identifier as a first information sequence and a group identifier as a second information sequence, or vice versa.

Another method to identify more devices is to use a new identifier domain other than current terminal media access control (MAC) address domain. A BS (e.g., a transmitting device) may indicate to a receiving device which domain identifier the BS is using for the receiving device, and the receiving device sets its behavior according to the identifier domain in which it is located.

To identify the devices with identifiers in new domain, a new resource grant signaling channel may be introduced. According to the IEEE 802.16m and/or IEEE 802.16e technical standards, a new MAP may be broadcasted on new radio resource. While, according to the 3GPP LTE technical standards, a new DPCCH may be broadcasted on a new radio resource or a new channel may be introduced for the second identifier domain.

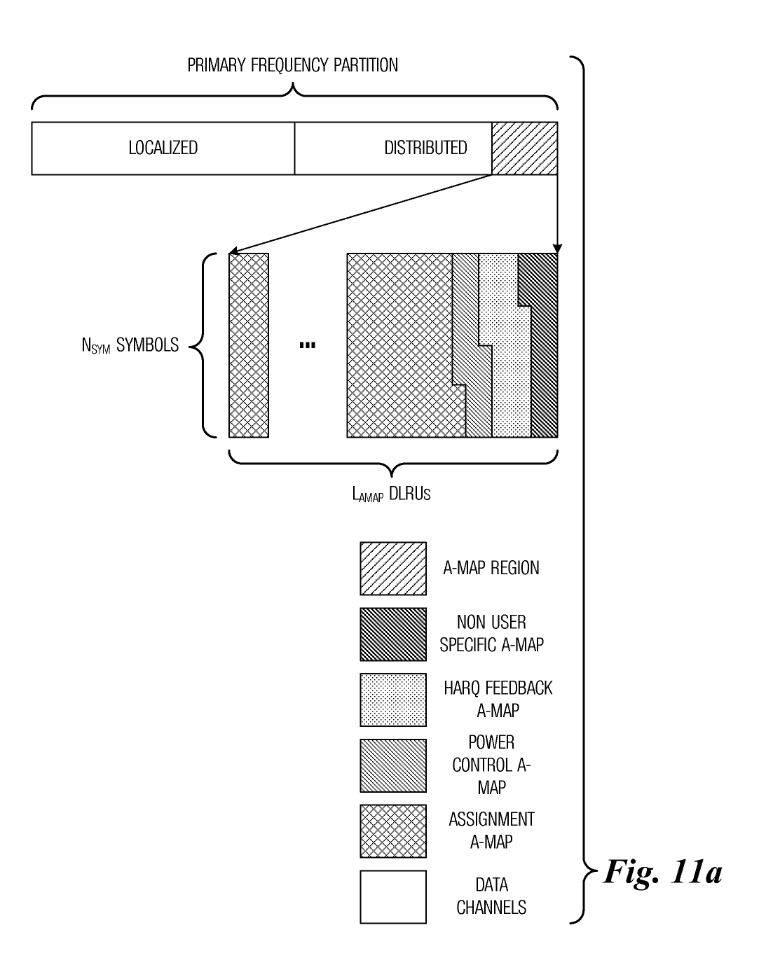

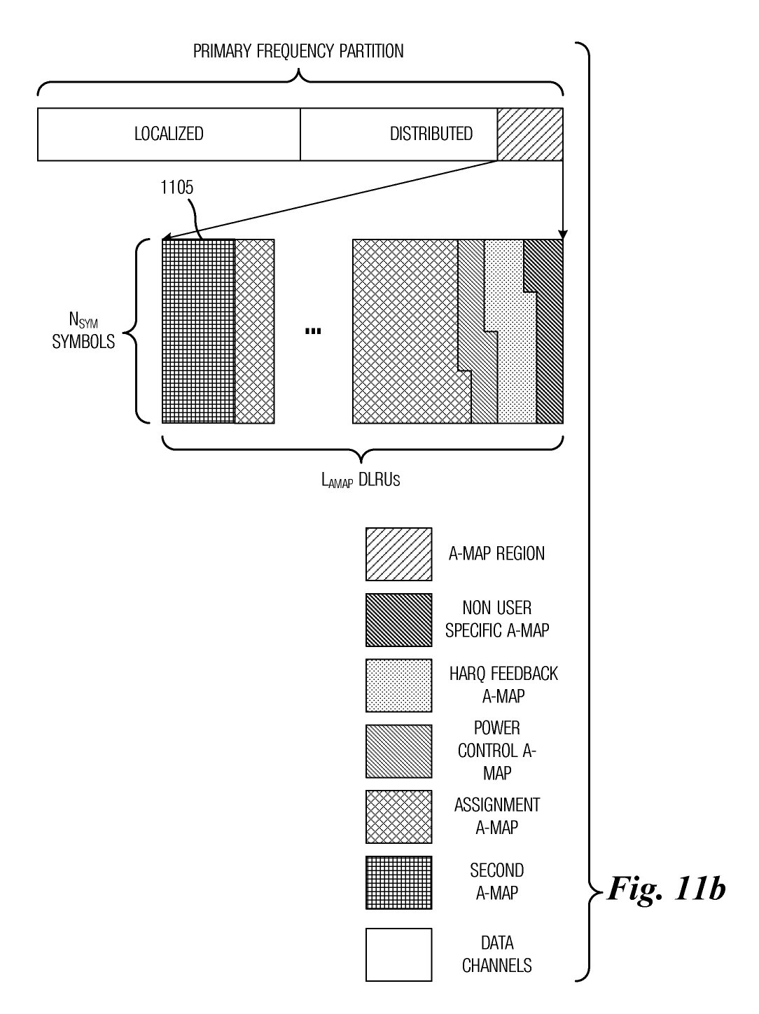

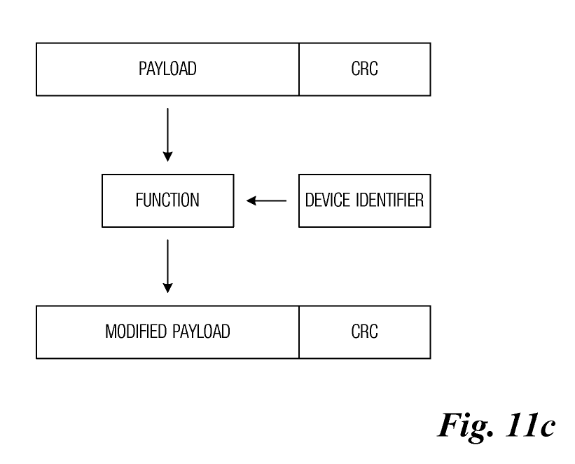

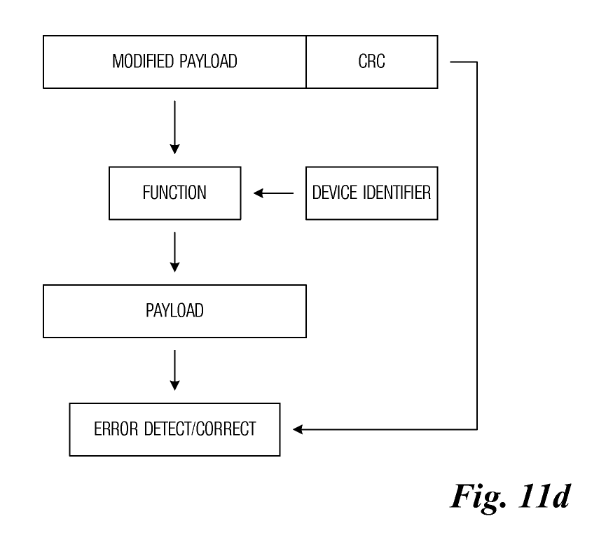

FIG. 11a illustrates a MAP architecture for the current IEEE 802.16m technical standards. FIG. 11b illustrates a MAP architecture modified with a second assignment A-MAP 1105 for a new identifier domain. According to the MAP architecture shown in FIG. 11b, a communications device receives second assignment A-MAP 1105 in another radio resource.

FIG. 11c illustrates a diagram of a technique at a source communications device for identifying a communications device(s) using a new identifier domain. FIG. 11d illustrates a diagram of a technique at a recipient communications device for identifying a communications device(s) using a new identifier domain.

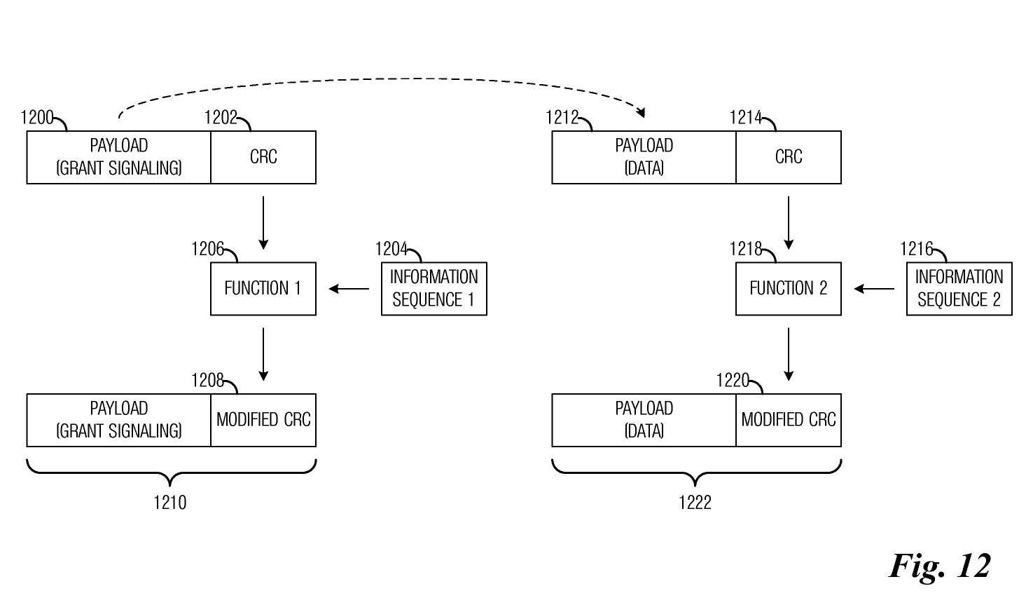

FIG. 12 illustrates a diagram of a technique at a transmitting device for providing multiple level identifier information to a receiving device. A first payload 1200, which may contain grant signaling information, and a first CRC 1202, which may correspond to first payload 1200, is to be transmitted by the transmitting device to the receiving device. In order to address first payload 1200 to the receiving device, first CRC 1202 may be modified with a first information sequence 1204 associated with the receiving device using first function 1206, which may be any function, such as an XOR or XNOR function, to produce a first modified CRC 1208. Collectively, first payload 1200 and first modified CRC 1208 may be referred to as transmission 1210.

A second payload 1212 and its associated CRC 1214 may be similarly addressed with a second information sequence 1216 also associated with the receiving device and a second function 1218 to produce a second modified CRC 1220. Collectively, second payload 1212 and second modified CRC 1220 may be referred to as transmission 1222.

According to an example embodiment, first payload 1200 and second payload 1212 may be used to carry multi-level (e.g., two-level) information. As an example, to carry a second level identifier or another information sequence, the second level identifier or another information sequence may be carried in a data packet (second payload 1212) which is transmitted on the resource indicated on the resource grant signaling (first payload 1200). According to another example embodiment, the second level identifier can be carried on the resource grant signaling (first payload 1200) while the first level identifier be carried on the data packet (second payload 1212).

Each of the identifiers or information sequences may be conveyed using the techniques described above. For example, the identifiers or information sequences may be used to modify a CRC, modify a payload, appended to a payload used in CRC calculations, or combinations thereof.

As shown in FIG. 12, the identifiers or information sequences are shown as being used to modify CRCs. However, other techniques, such as those described previously may also be used. As an example, the identifiers or information sequences may be embedded into payloads, which are then used to generate CRCs. Furthermore, different techniques may be used with different identifiers or information sequences. For example, a first identifier (or information sequence) may be used to modify a CRC and a second identifier (or information sequence) may be embedded in a payload.

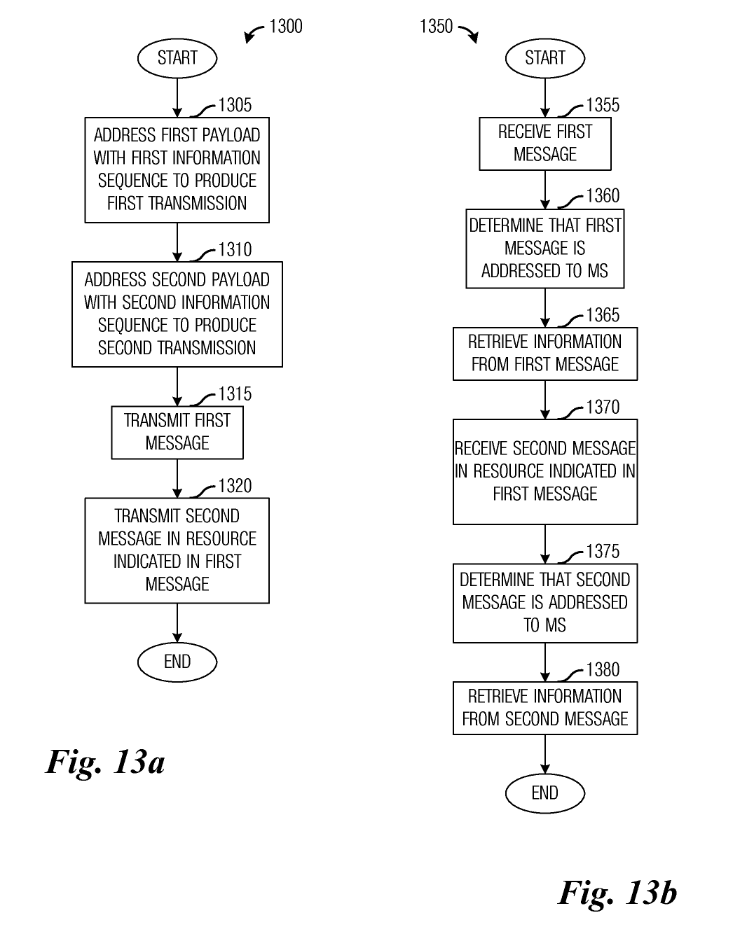

FIG. 13a illustrates a flow diagram of operations 1300 in a transmitting device providing multiple level identifier information to a receiving device. Operations 1300 may be indicative of operations occurring in a transmitting device, such as BS 205, as the transmitting device provides multiple level identifier information to a receiving device.

Operations 1300 may begin with the transmitting device addressing a first payload or first message with a first information sequence associated with the receiving device (block 1305). According to an example embodiment, the transmitting device may address the first payload or the first message by embedding the first information sequence with the first payload or combining the first information sequence with either the first payload or a first CRC using any of the techniques discussed herein.

The transmitting device may address a second payload or second message with a second information sequence associated with the receiving device (block 1310). According to an example embodiment, the transmitting device may address the second payload or the second message by embedding the second information sequence with the second payload or combining the second information sequence with either the second payload or a second CRC using any of the techniques discussed herein.

The transmitting device may then transmit the first message (block 1315) and the second message (block 1320). In an example embodiment, the transmission of the second message may occur in a network resource indicated by the first message. Alternatively, the transmitting device may transmit the second message and the first message, with the first message transmitted in a network resource indicated by the second message.

FIG. 13b illustrates a flow diagram of operations 1350 in a receiving device as it receives multiple level identifier information from a transmitting device. Operations 1350 may be indicative of operations occurring in a receiving device, such as MS 210, MS 212, and MS 214, as the receiving device receives multiple level identifier information from the transmitting device.

Operations 1350 may begin with the receiving device receiving a first message (block 1355). The first message may contain a payload and a CRC, where either the payload or the CRC or both the payload and the CRC has been addressed to a communications device that may or may not be the receiving device. The payload and/or the CRC may be addressed to the communications device using an information sequence or a plurality of information sequences associated with the communications device. The use of the information sequence or the plurality of information sequences to address the payload and/or the CRC may be according to one or more of the techniques described herein.

The receiving device may determine that the first message is addressed to it (block 1360). The receiving device may use one or more of the techniques described herein to determine that the first message is addressed to it. The receiving device may retrieve information from the first message (block 1365).

The receiving device may receive a second message in a resource indicated by the first message (block 1370). The second message may contain a payload and a CRC, where either the payload or the CRC or both the payload and the CRC has been addressed to a communications device that may or may not be the receiving device. The payload and/or the CRC may be addressed to the communications device using an information sequence or a plurality of information sequences associated with the communications device. The use of the information sequence or the plurality of information sequences to address the payload and/or the CRC may be according to one or more of the techniques described herein.

The receiving device may determine that the second message is addressed to it (block 1375). The receiving device may use one or more of the techniques described herein to determine that the second message is addressed to it. The receiving device may retrieve information from the second message (block 1380).

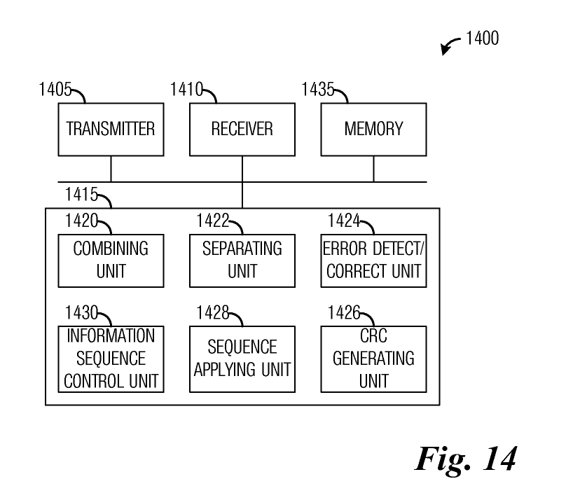

FIG. 14 illustrates a communications device 1400. Communications device 1400 may be an implementation of a transmitting device or a receiving device. Communications device 1400 may be used to implement various ones of the embodiments discussed herein. As shown in FIG. 14, a transmitter 1405 is configured to transmit information and a receiver 1410 is configured to receive information. Transmitter 1405 and receiver 1410 may have a wireless interface, a wireline interface, or a combination thereof.

A combining unit 1420 is configured to combine sequences to form a single sequence. Combining unit 1420 is also configured to embed one sequence into another sequence. Combining unit 1020 may be configured to follow a range of combination rules. A separating unit 1422 is configured to separate a sequence into multiple sequences. Separating unit 1422 may be configured to separate the sequence at provided locations. An error detect and correct unit 1424 is configured to detect and/or correct errors in a sequence using another sequence, e.g., a CRC.

A CRC generating unit 1426 is configured to generate a CRC from a sequence. CRC generate unit 1426 may make use of a rule(s) to generate the CRC. A sequence applying unit 1428 is configured to apply a first sequence to a second sequence based on a specified function, such as an XOR or XNOR function. An information sequence control unit 1430 is configured to control a combination of sequences, a separation of sequences, and an application of sequences. A memory 1435 is configured to store information, such as rules for combining, separating, and applying sequences, the sequences themselves, and so on.

The elements of communications device 1400 may be implemented as specific hardware logic blocks. In an alternative, the elements of communications device 1400 may be implemented as software executing in a processor, controller, application specific integrated circuit, or so on. In yet another alternative, the elements of communications device 1400 may be implemented as a combination of software and/or hardware.

As an example, transmitter 1405 and receiver 1410 may be implemented as a specific hardware block, while combining unit 1420, separating unit 1422, error detect and correct unit 1424, CRC generating unit 1426, sequence applying unit 1428, and information sequence control unit 1430 may be software modules executing in a microprocessor (such as processor 1415), a custom circuit, a custom compiled logic array of a field programmable logic array, or combinations thereof.

According to an example embodiment, at a recipient communications device, the identifiers or information sequences may be retrieved by the recipient communications device using a technique(s) appropriate to a technique(s) used at the source communications device address the transmissions.

Although the discussion presented above focused on a single information sequence, the example embodiments may be extended to multiple information sequences with changes that are obvious to those of ordinary skill in the art of the example embodiments. Therefore, the discussion of single information sequences should not be construed as being limiting to either the scope or spirit of the example embodiments.

Advantageous features of embodiments of the disclosure may include: a method for communications device operations, the method includes combining a payload with a first information sequence, thereby producing an error sequence; determining an error check for the error sequence; and transmitting the payload and the error check.

The method could further include, wherein the first information sequence comprises a plurality of information sequences. The method could further include, wherein combining the payload with the first information sequence comprises appending the first information sequence to the payload. The method could further include, wherein combining the payload with the first information sequence comprises inserting the first information sequence into the payload.

The method could further include, wherein combining the payload with the first information sequence comprises combining the payload, the first information sequence, and an indicator. The method could further include, wherein the first information sequence comprises identification information. The method could further include, further comprising applying a second information sequence to the error check.

The method could further include, wherein applying a second information sequence comprises applying the second information sequence to the error check with a function. The method could further include, wherein the function comprises an exclusive OR function.

Advantageous features of embodiments of the disclosure may include: a communications device including a combine unit configured to combine a payload and a first information sequence to produce an error sequence; an error check generate unit coupled to the combine unit, the error check generate unit configured to determine an error check for the error sequence; and a transmitter coupled to the combine unit and to the error check generate unit, the transmitter configured to transmit the payload and the error check.

The communications device could further include, wherein the first information sequence comprises a plurality of information sequences. The communications device could further include, wherein the combine unit is further configured to combine an indicator with the payload and the first information sequence. The communications device could further include, further comprising a sequence apply unit coupled to the error check generate unit, the sequence apply unit configured to apply a second information sequence to the error check, wherein the second information sequence is applied based on a function. The communications device could further include, wherein the function comprises an exclusive OR function.

Advantageous features of embodiments of the disclosure may include: a method for communications device operations, the method including combining a first information sequence to a payload, thereby producing a modified payload; determining an error check for the payload; and transmitting the modified payload and the error check.

The method could further include, wherein applying a first information sequence comprises appending the payload to the first information sequence. The method could further include, wherein applying a first information sequence comprises embedding the payload in the first information sequence. The method could further include, further comprising applying a second information sequence to the error check.

The method could further include, wherein applying a second information sequence comprises applying the second information sequence to the error check with a function. The method could further include, wherein the function comprises an exclusive OR function. The method could further include, wherein the first information sequence comprises identification information.

Advantageous features of embodiments of the disclosure may include: a communications device including a combine unit configured to combine a payload and a first information sequence to produce a modified payload; an error check generate unit coupled to the combine unit, the error check generate unit configured to determine an error check for the modified payload; and a transmitter coupled to the combine unit and to the error check generate unit, the transmitter configured to transmit the payload and the error check

The communications device could further include, wherein the first information sequence comprises a plurality of information sequences. The communications device could further include, wherein the combine unit is further configured to combine an indicator with the payload and the first information sequence. The communications device could further include, further comprising a sequence apply unit coupled to the error check generate unit, the sequence apply unit configured to apply a second information sequence to the error check, wherein the second information sequence is applied based on a function. The communications device could further include, wherein the function comprises an exclusive OR function.

Advantageous features of embodiments of the disclosure may include: a method for communications device operations, the method including transmitting a first payload to a communications device, wherein the first payload comprises an indication for a second payload, and wherein the first payload is marked by a first information sequence; and transmitting the second payload to the communications device, wherein the second payload is marked by a second information sequence.

The method could further include, wherein the first information sequence comprises first level information and the second information sequence comprises second level information. The method could further include, wherein the first information sequence comprises second level information and the second information sequence comprises first level information.

Although the present disclosure and its advantages have been described in detail, it should be understood that various changes, substitutions and alterations can be made herein without departing from the spirit and scope of the disclosure as defined by the appended claims.

What is claimed is:

1. A method of transmitting an information sequence in a message, the method comprising:
embedding a first information sequence into an original payload of the message to produce an augmented payload;
generating an original error check code using the augmented payload, the original error check code derived from the first information sequence; and
transmitting the message, the message including the original payload and the original error check code.

2. The method of claim 1, wherein the first information sequence comprises an identifier of an intended recipient of the message, security information, a security key, processing information, coordinating information, configuring information, an identifier of a type of the message, an identifier of a class of the message, an identifier of a source of the message, or a combination thereof.

3. The method of claim 1, further comprising:
modifying the original error check code with a second information sequence to produce an augmented error check code, the augmented error check code derived from the second information sequence; and
transmitting the message, the message including the original payload and the augmented error check code.

4. The method of claim 3, wherein modifying the original error check code with the second information sequence comprises providing the original error check code and the second information sequence to a function to produce the augmented error check code.

5. The method of claim 4, wherein the function comprises an exclusive OR function or an exclusive NOR function.

6. The method of claim 1, wherein embedding the first information sequence comprises appending, concatenating, or interleaving the first information sequence to the original payload.

7. The method of claim 1, wherein the first information sequence is used identify an intended recipient of the message, and wherein transmitting the message comprises broadcasting the message to multiple recipients.

8. A method of receiving a message by a receiving device, the method comprising:
receiving the message including an original payload and an original error check code;
embedding a first information sequence into the original payload to produce a local payload;
performing an error check on the local payload using the original error check code; and
determining that the message is embedded with the first information sequence if the error check succeeded.

9. The method of claim 8, further comprising:
modifying the original error check code with a second information sequence to produce a local error check code; and
performing an error check on the local payload using the local error check code.

10. The method of claim 9, wherein modifying the original error check code with the second information sequence comprises providing the original error check code and the second information sequence to a function to produce the local error check code.

11. The method of claim 10, wherein the function comprises an exclusive OR function or an exclusive NOR function.

12. The method of claim 8, wherein embedding the first information sequence comprises appending, concatenating, or interleaving the first information sequence to the original payload.

13. The method of claim 8, wherein the first information sequence is used identify an intended recipient of the message, and wherein determining that the message is embedded with the first information sequence comprises determining that the receiving device is the intended recipient of the message.

14. A method of transmitting an information sequence in a message, the method comprising:
modifying an original payload of the message with a first information sequence to derive an augmented payload;
generating an original error check code using the original payload; and
transmitting the message, the message including the augmented payload and the original error check code.

15. The method of claim 14, wherein modifying the original payload with the first information sequence comprises providing the original payload and the first information sequence to a first function to derive the augmented payload.

16. The method of claim 14, further comprising:
modifying the original error check code with a second information sequence to derive an augmented error check code; and
transmitting the message, the message including the augmented payload and the augmented error check code.

17. The method of claim 16, wherein modifying the original error check code with the second information sequence comprises providing the original error check code and the second information sequence to a second function to derive the augmented error check code.

18. A method of receiving a message by a receiving device, the method comprising:
receiving the message including an augmented payload and an original error check code;
modifying the augmented payload with a first information sequence to derive a local payload;
performing an error check on the local payload using the original error check code; and
determining that the message is embedded with the first information sequence if the error check succeeded.

19. The method of claim 18, wherein modifying the augmented payload with the first information sequence comprises providing the augmented payload and the first information sequence to a first function to derive the local payload.

20. The method of claim 18, further comprising:
modifying the original error check code with a second information sequence to produce a local error check code; and
performing an error check on the local payload using the local error check code.

21. The method of claim 20, wherein modifying the original error check code with the second information sequence comprises providing the original error check code and the second information sequence to a second function to produce the local error check code.

22. A transmitting device comprising:
a processor configured to embed a first information sequence into an original payload of a message to produce an augmented payload, and to generate an original error check code using the augmented payload, the original error check code derived from the first information sequence; and
a transmitter operatively coupled to the processor, the transmitter configured to transmit the message, the message including the original payload and the original error check code.

23. The transmitting device of claim 22, wherein the processor is configured to modify the original error check code with a second information sequence to produce an augmented error check code, the augmented error check code derived from the second information sequence, and wherein the transmitter is configured to transmit the message, the message including the original payload and the augmented error check code.

24. The transmitting device of claim 23, wherein the processor is configured to provide the original error check code and the second information sequence to a function to produce the augmented error check code.

25. The transmitting device of claim 24, wherein the function comprises an exclusive OR function or an exclusive NOR function.

26. A transmitting device comprising:
a processor configured to modify an original payload of a message with a first information sequence to derive an augmented payload, and to generate an original error check code using the original payload; and
a transmitter operatively coupled to the processor, the transmitter configured to transmit the message, the message including the augmented payload and the original error check code.

27. The transmitting device of claim 26, wherein the processor is configured to provide the original payload and the first information sequence to a first function to produce the augmented payload.

28. The transmitting device of claim 26, wherein the processor is configured to modify the original error check code with a second information sequence to produce an augmented error check code, the augmented error check code including a second formulation of the second information sequence, and wherein the transmitter is configured to transmit the message, the message including the augmented payload and the augmented error check code.

29. The transmitting device of claim 28, wherein the processor is configured to provide the original error check code and the second information sequence to a second function to produce the augmented error check code.
